(19) United States
(12) Patent Application Publication
(10) Pub. No.: US 2015/0034965 A1
(43) Pub. Date: Feb. 5, 2015

(54) LIGHT EMITTING DIODE AND METHOD FOR MANUFACTURING SAME

(71) Applicant: ADVANCED OPTOELECTRONIC TECHNOLOGY, INC., Hsinchu Hsien (TW)

(72) Inventors: YA-WEN LIN, Hsinchu (TW); CHING-HSUEH CHIU, Hsinchu (TW); PO-MIN TU, Hsinchu (TW); SHIH-CHENG HUANG, Hsinchu (TW)

(21) Appl. No.: 14/449,102

(22) Filed: Jul. 31, 2014

(30) Foreign Application Priority Data
Aug. 2, 2013 (CN) 2013103333276

(51) Int. Cl. H01L 33/24; H01L 33/00; H01L 33/58; H01L 33/32

(52) U.S. Cl. CPC H01L 33/24; H01L 33/32; H01L 33/0075; H01L 33/0025; H01L 33/58; H01L 2933/0091; H01L 2933/0058
USPC 257/76; 438/46

(57) ABSTRACT

An LED includes a substrate and a semiconductor structure mounted on the substrate. A plurality of first holes and a plurality of second holes are defined in the semiconductor structure. The second holes are located above the first holes and communicate with the first holes. A method for manufacturing the LED is also provided.

### FIELD

The present disclosure generally relates to solid state light emitting sources and, more particularly, to a light emitting diode (LED) and a method for manufacturing the LED.

### BACKGROUND

LEDs have many advantages, such as high luminosity, low operational voltage, low power consumption, compatibility with integrated circuits, easy driving, long term reliability, and environmental friendliness which have promoted the wide use of LEDs as a light source.

A typical LED includes a substrate, an N-type semiconductor layer, an active layer and a P-type semiconductor layer formed on the substrate in series. A part of light emitted from the active layer traverses through the P-type semiconductor layer to illuminate; the other part of light is totally reflected back into an interior of the LED by an outer surface of the P-type semiconductor layer to be wasted. Thus, the light extraction efficiency of the LED must to be improved.

Therefore, what is needed, is an LED and a method for manufacturing the LED which can overcome the limitations described above.

### BRIEF DESCRIPTION OF THE DRAWINGS

FIG. 1 is an isometric view of an LED according to an exemplary embodiment of the present disclosure.

FIGS. 2-3 are schematic views showing steps of a method for manufacturing the LED of FIG. 1.

### DETAILED DESCRIPTION

An LED 100 in accordance with an embodiment of the present disclosure will now be described in detail below and with reference to the drawings.

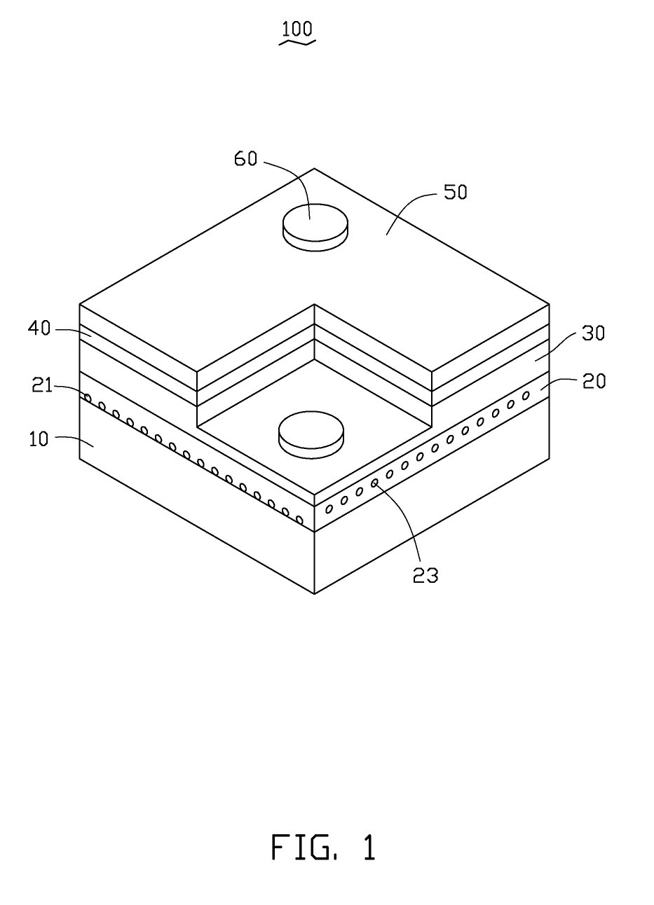

Referring to FIG. 1, the LED 100 includes a substrate 10 and a semiconductor structure formed on the substrate 10. The semiconductor structure includes an un-doped GaN layer 20, an N-type GaN layer 30, an active layer 40 and a P-type GaN layer 50 arranged on a top surface of the substrate 10 in series.

In this embodiment, the substrate 10 is a rectangular sapphire layer, and the active layer 40 is a multiple quantum well layer. A bottom surface of the un-doped GaN layer 20 entirely covers the top surface of the substrate 10. The semiconductor structure is etched from top to bottom until a part of the P-type GaN layer 50, a part of the active layer 40, and a part of the N-type GaN layer 30 are removed and a part of the N-type GaN layer 30 is exposed. Two electrodes 60 are respectively mounted on the P-type GaN layer 50 and the exposed part of the N-type GaN layer 30.

A plurality of first holes 21 and a plurality of second holes 23 are defined in the un-doped GaN layer 20. The first holes 21 are defined along a transverse direction of the un-doped GaN layer 20 and extend through opposite sides of the un-doped GaN layer 20 at the transverse direction. The first holes 21 are spaced from each other. The second holes 23 are located above the first holes 21, defined along a longitudinal direction of the un-doped GaN layer 20 and extend through opposite ends of the un-doped GaN layer 20 at the longitudinal direction. The second holes 23 are spaced from each other. Bottom ends of the second holes 23 communicate top ends of the first holes 21. Each first hole 21 and second hole 23 is an elongated, cylindrical hole. A bottom end of the first hole 21 is coplanar with a bottom surface of the un-doped GaN layer 20 and is closed by the top surface of the substrate 10. The second holes 23 are located at a middle portion of the un-doped GaN layer 20 along a height direction of the un-doped GaN layer 20. A diameter of the first hole 21 and the second hole 23 is varied between 10 nanometer to 40 nanometer. In the depicted embodiment, the diameter of the first hole 21 is equal to that of the second hole 23 and is 20 nanometer. Air is contained in the first holes 21 and the second holes 23. Because the refractive index of the air is different from that of the un-doped GaN layer 20, light arrived at the interfaces between the un-doped GaN layer 20 and the first holes 21, and between the un-doped GaN layer 20 and the second holes 23 is reflected.

When a part of light emitted from the active layer 40 is arrived to the first holes 21 and the second holes 23, the light is reflected by the interfaces between the un-doped GaN layer 20 and the first and second holes 21, 23 several times to change the incidence angle of the light to make the light travel bias away the substrate 10 and avoid or tremendously decrease the absorption of the substrate 10. Therefore, the light extraction efficiency of the LED 100 is improved.

The present disclosure further provides a method for manufacturing the LED 100 of FIG. 1.

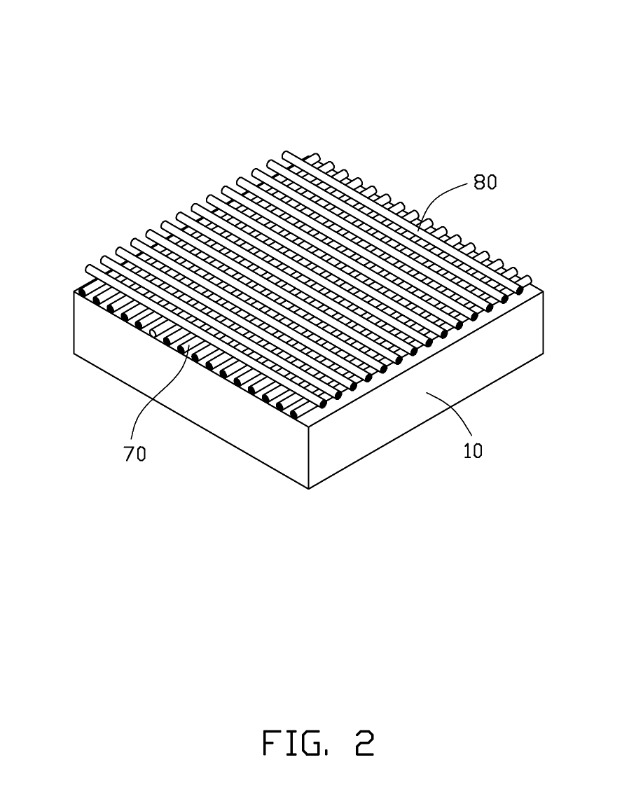

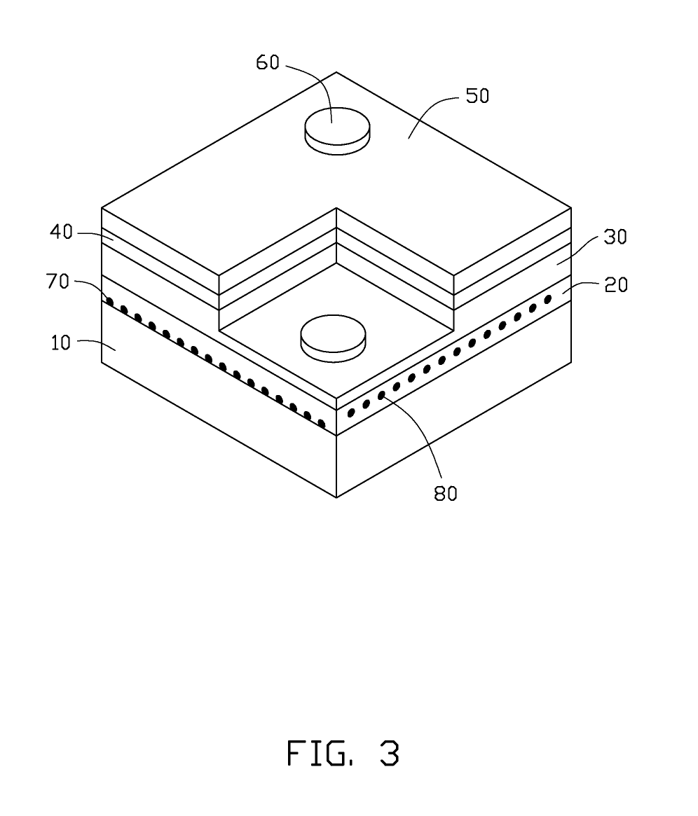

Referring to FIGS. 2-3, in the first step, the substrate 10, a plurality of first carbon nanotubes 70 and a plurality of second carbon nanotubes 80 are provided. The first carbon nanotubes 70 and the second carbon nanotubes 80 are arranged on the top surface of the substrate 10 by van der Waals force. The first carbon nanotubes 70 are spaced from each other and arranged on the top surface of the substrate 10. The first carbon nanotubes 70 are parallel to each other and arranged along the transversal direction of the substrate 10. Opposite ends of each first carbon nanotubes 70 are respectively coplanar with the opposite sides of the substrate 10. The second carbon nanotubes 80 are spaced from each other and arranged on the top ends of the first carbon nanotubes 70. The second carbon nanotubes 80 are parallel to each other and arranged along the longitudinal direction of the substrate 10. Opposite ends of each second carbon nanotubes 80 are respectively coplanar with the opposite ends of the substrate 10. Each first carbon nanotube 70 and second carbon nanotube 80 is an elongated, cylindrical tube. A diameter of the first carbon nanotube 70 and the second carbon nanotube 80 is varied between 10 nanometer to 40 nanometer. In the depicted embodiment, the diameter of the first carbon nanotube 70 is equal to that of the second carbon nanotube 80 and is 20 nanometer.

In the second step, the semiconductor structure is grown on the top surface of the substrate 10 and enclosing the first carbon nanotubes 70 and the second carbon nanotubes 80 therein. The semiconductor structure includes the un-doped GaN layer 20, the N-type GaN layer 30, the active layer 40 and the P-type GaN layer 50 grown on the top surface of the substrate 10 in series. The un-doped GaN layer 20 grows from gaps between the first carbon nanotubes 70 and the second carbon nanotubes 80 until the un-doped GaN layer 20 encloses the top ends of the second carbon nanotubes 80 to decrease lattice defect of the semiconductor structure.

In the third step, the semiconductor structure is etched from top to bottom until a part of the P-type GaN layer 50, a part of the active layer 40, and a part of the N-type GaN layer 30 are removed and a part of the N-type GaN layer 30 is exposed. The electrodes 60 are respectively mounted on the P-type GaN layer 50 and the exposed N-type GaN layer 30.

In the fourth step, the first carbon nanotubes 70 and the second carbon nanotubes 80 are removed to define the first holes 21 and the second holes 23 in the un-doped GaN layer 20. In this embodiment, the first carbon nanotubes 70 and the second carbon nanotubes 80 are radiated by laser having an energy intensity of 0.15˜10 w/cm² to become gas. Generally, when the substrate 10 and the un-doped GaN layer 20 are radiated by larger than 4000˜5000 w/cm² laser, the substrate 10 will be stripped from the un-doped GaN layer 20. So, when the first carbon nanotubes 70 and the second carbon nanotubes 80 are removed, the substrate 10 combines the un-doped GaN layer 20 together stably.

It is to be further understood that even though numerous characteristics and advantages of the present embodiments have been set forth in the foregoing description, together with details of the structures and functions of the embodiments, the disclosure is illustrative only, and changes may be made in detail, including in matters of shape, size, and arrangement of parts within the principles of the disclosure to the full extent indicated by the broad general meaning of the terms in which the appended claims are expressed.

What is claimed is:

1. A light emitting diode (LED) comprising:
a substrate; and
a semiconductor structure grown on the substrate;
wherein a plurality of first holes and a plurality of second holes are defined in the semiconductor structure, the second holes are located above the first holes and communicate with the first holes.

2. The LED of claim 1, wherein the first holes are spaced from each other, the second holes are spaced from each other, and bottom ends of the second holes communicate top ends of the first holes.

3. The LED of claim 2, wherein the semiconductor structure comprises an un-doped GaN layer, the first holes and the second holes are defined in the un-doped GaN layer, the first holes are defined along a transverse direction of the un-doped GaN layer, and the second holes are defined along a longitudinal direction of the un-doped GaN layer.

4. The LED of claim 3, wherein the first holes extend through opposite sides of the un-doped GaN layer, and the second holes extend through opposite ends of the un-doped GaN layer.

5. The LED of claim 1, wherein each first hole and second hole is an elongated, cylindrical hole.

6. The LED of claim 5, wherein a diameter of the first hole and the second hole is varied between 10 nanometer to 40 nanometer.

7. The LED of claim 6, wherein the diameter of the first hole is equal to that of the second hole and is 20 nanometer.

8. The LED of claim 3, wherein a bottom end of the first hole is coplanar with a bottom surface of the un-doped GaN layer and is closed by a top surface of the substrate.

9. The LED of claim 3, wherein the semiconductor structure further comprises an N-type GaN layer, an active layer and a P-type GaN layer arranged on the un-doped GaN layer in series.

10. A method for manufacturing a light emitting diode (LED), the method comprising:
providing a substrate, a plurality of first carbon nanotubes and a plurality of second carbon nanotubes, the first carbon nanotubes arranged on the substrate, and the second carbon nanotubes arranged on the first carbon nanotubes;
growing a semiconductor structure from the substrate to enclose the first carbon nanotubes and the second carbon nanotubes therein; and
removing the first carbon nanotubes and the second carbon nanotubes to define a plurality of first holes and a plurality of second holes in the semiconductor structure.

11. The method of claim 10, wherein the first carbon nanotubes are parallel to each other and arranged along the transversal direction of the substrate, and second carbon nanotubes are parallel to each other and arranged along the longitudinal direction of the substrate.

12. The method of claim 10, wherein each first carbon nanotube and second carbon nanotube is an elongated, cylindrical tube.

13. The method of claim 12, wherein a diameter of the first carbon nanotube and the second carbon nanotube is varied between 10 nanometer to 40 nanometer.

14. The method of claim 13, wherein the diameter of the first carbon nanotube is equal to that of the second carbon nanotube and is 20 nanometer.

15. The method of claim 10, wherein the step of removing the first carbon nanotubes and the second carbon nanotubes is performed by subjecting the first carbon nanotubes and the second carbon nanotubes to a laser radiation having an energy intensity of 0.15˜10 w/cm² laser to become gas.

16. An LED, comprising a substrate and a semiconductor structure which having several layers formed on the substrate successively along a vertical direction, wherein a plurality of holes are defined in the semiconductor structure and extend through the semiconductor structure along a horizontal direction.

17. The LED of claim 16, wherein the holes comprise upper holes and lower holes perpendicular to the upper holes, and wherein the upper holes are parallel to each other while the lower holes are parallel to each other.

18. The LED of claim 17, wherein each of the holes is an elongated, cylindrical hole.
